(19) United States
(12) Patent Application Publication
(10) Pub. No.: US 2021/0005513 A1
(43) Pub. Date: Jan. 7, 2021

(54) METHOD OF FABRICATING A SEMICONDUCTOR DEVICE

(71) Applicant: WUHAN XINXIN SEMICONDUCTOR MANUFACTURING CO., LTD., Wuhan, Hubei (CN)

(72) Inventors: Baoying SONG, Wuhan, Hubei (CN); Yan XIE, Wuhan, Hubei (CN)

(21) Appl. No.: 16/626,772

(22) PCT Filed: Nov. 19, 2019
(86) PCT No.: PCT/CN2019/119523

§ 371 Date: Dec. 26, 2019

(30) Foreign Application Priority Data
Jul. 2, 2019 (CN) 201910590682.9

(51) Int. Cl. H01L 21/768; H01L 21/02; H01L 21/311

(52) U.S. Cl. CPC H01L 21/76898; H01L 21/02118; H01L 21/31138; H01L 21/0228; H01L 21/31116; H01L 21/02274

(57) ABSTRACT

A method of fabricating a semiconductor device, including: providing a front-end component including a substrate, a dielectric layer on a front side of the substrate, a metal layer embedded in the dielectric layer, a hole and an isolation layer; forming a polymer layer which covers a surface of the isolation layer; removing a portion of the polymer layer and at least a partial thickness of a portion of the isolation layer over the bottom of the hole by etching both the polymer layer and the isolation layer; removing the polymer layer; and successively repeating steps of forming a polymer layer, etching both the polymer layer and the isolation layer and removing the polymer layer, until the metal layer is exposed. This method ensures that the metal layer is exposed without loss of the isolation layer over a side wall of the hole and a top surface of the front-end component.

### TECHNICAL FIELD

The present invention relates to the field of semiconductor devices and, more particularly, to a method of fabricating a semiconductor device.

### BACKGROUND

Driven by the ever-persistent demand for electronic products with lighter, thinner, shorter and smaller physical dimensions and properties as well as more and more diverse functions, the current research and development efforts in the IC packaging industry are focused on maximizing the thickness utilization, and three-dimensional integrated circuit (3DIC) technology is considered as a key technology to meet the above requirements. The 3DIC technology aims to three-dimensionally stack IC chips using through silicon vias (TSVs) or the like so that they can provide the best performance while having the smallest footprint.

A 3DIC process often involves exposing a layer of a first metal for subsequent connection under a substrate of a stacked wafer by forming a hole extending through the substrate and protecting the so-exposed substrate and metal layer from possible adverse effects by covering a side wall and bottom of the hole as well as a top surface of the wafer with an isolation layer. Therefore, the subsequent process for filling a second metal in the hole and thus connecting it to the first metal is preceded by exposing the underlying first metal layer through etching away the isolation layer portion covering the bottom of the hole.

Conventional techniques for removing those isolation layer portions tend to also cause partial loss of the remainder of the isolation layer over the side walls of the holes and the top surface of the wafer, leading to unwanted exposure which may degrade the performance of the semiconductor devices being fabricated.

### SUMMARY OF THE INVENTION

It is just an objective of the present invention to protect the isolation layer portion that covers the holes' side walls and the wafer top surface during the removal of the remaining isolation layer portions over the hole bottoms to prevent exposure of the substrate and the top surface of the front-end components, thereby improving the performance of the semiconductor devices being fabricated.

The present invention provides a method of fabricating a semiconductor device, including: providing a front-end component including a substrate, a dielectric layer on a front side of the substrate, a metal layer embedded in the dielectric layer, a hole and an isolation layer, the hole penetrating through at least the substrate and exposing the metal layer, the isolation layer covering a side wall and a bottom of the hole, the metal layer and a back side of the substrate; forming a polymer layer which covers a surface of the isolation layer; removing a portion of the polymer layer and at least a partial thickness of a portion of the isolation layer over the bottom of the hole by etching both the polymer layer and the isolation layer; removing the polymer layer; and successively repeating the steps of forming a polymer layer, etching both the polymer layer and the isolation layer and removing the polymer layer, until the metal layer is exposed.

Additionally, the polymer layer may be formed by a plasma deposition process performed at a plasma chamber pressure of from 25 mTorr to 35 mTorr, an RF power level of 2000-3000 W and a bias voltage of 45-55 V using mixed reaction gases including CH₂F₂, CH₃F and O₂.

Additionally, CH₂F₂, CH₃F and O₂ may be provided at flow rates of 140-160, 190-210 and 15-25 sccm, respectively, for a period of time of 6-8 s.

Additionally, the polymer layer and isolation layer may be etched by a plasma etching process performed at a plasma chamber pressure of from 10 mTorr to 20 mTorr, an RF power level of 1000-2500 W and a bias voltage of 1400-1600 V using mixed reaction gases including NF₃, CH₃F, CHF₃ and O₂.

Additionally, NF₃, CH₃F, CHF₃ and O₂ may be provided at flow rates of 70-90, 50-70, 40-60 and 8-12 sccm, respectively, for a period of time of 13-17 s.

Additionally, the polymer layer may be removed by an ashing process performed for a period of time of 23-27 s at a plasma chamber pressure of from 15 mTorr to 25 mTorr, an RF power level of 2500-2700W and a bias voltage of 0 V using a reaction gas containing 0₂ introduced at a flow rate of 800-1200 sccm.

Additionally, the steps of forming a polymer layer, etching both the polymer layer and the isolation layer and removing the polymer layer may be successively repeated for 8 to 10 times.

Additionally, the hole may extend through the substrate so that the metal layer is exposed therein.

Additionally, the hole may extend through both the substrate and a partial thickness of the dielectric layer so that the metal layer is exposed therein.

Additionally, the polymer layer may have a thickness ranging from 5 nm to 20 nm.

Compared with the prior art, the present invention offers the following advantages:

The steps of forming a polymer layer, etching both the polymer layer and the isolation layer and removing the polymer layer are successively repeated until the metal layer is exposed. During the etching removal of the isolation layer portion over the bottom of the hole, a polymer is deposited to protect the isolation layer portion over the side wall of the hole. In addition, in order to prevent the accumulation of an excessive amount of the polymer, which may cause the etching process to stop in an undesirable way, the etching removal of the isolation layer portion over the bottom of the hole is accomplished in a number of repeated cycles each including forming a new polymer layer and then removing it. In this way, it can be ensured that the metal layer is exposed without loss of the solation layer portion over the side wall of the hole and a top surface of the front-end component. As a result, undesirable exposure of the substrate or the front-end component's top surface is prevented, resulting in enhanced performance and yield of the semiconductor devices being fabricated.

### BRIEF DESCRIPTION OF DRAWINGS

FIG. 1 schematically shows a flowchart of a method of fabricating a semiconductor device in accordance with an embodiment of the present invention.

FIG. 2-a is a structural schematic of a front-end component according to an embodiment of the present invention.

FIG. 2-b is a structural schematic of a front-end component according to another embodiment of the present invention.

FIG. 3 schematically illustrates the formation of a polymer layer according to an embodiment of the present invention.

FIG. 4 schematically illustrates how a polymer layer and an isolation layer are etched in accordance with an embodiment of the present invention.

FIG. 5 is a schematic illustration of a structure with a metal layer being exposed according to an embodiment of the present invention.

In these figures,

11—substrate; 11a—back side of the substrate; 11b—front side of the substrate; 21—dielectric layer; 31—metal layer; 41—hole; 51—passivation layer; 61—isolation layer;

12—substrate; 12a—back side of the substrate; 12b—front side of the substrate; 22—dielectric layer; 32—metal layer; 42—hole; 52—passivation layer; 62—isolation layer; 70—polymer layer.

### DETAILED DESCRIPTION OF EXEMPLARY EMBODIMENTS

As discussed in the Background section, in the course that the isolation layer portion covering the bottom of the hole is etched away, it is very likely for the remainder of the isolation layer that covers the wafer top surface and the side wall of the hole to be also partially removed and thus undesirably expose the substrate. Specifically, this partial loss of the isolation layer tends to occur around an upper edge of the hole and over the side wall thereof and, when it happens, the second metal layer subsequently filled into the hole to interconnect with the first metal layer will easily diffuse into the substrate, which is unfavorable to the performance of the semiconductor devices being fabricated.

According to embodiments of the present invention, steps of forming a polymer layer, etching both the polymer layer and the isolation layer and removing the polymer layer are successively repeated until the isolation layer portion covering the bottom of the hole is completed removed to expose the metal layer. During the etching removal of the isolation layer portion over the bottom of the hole, a polymer is deposited to protect the isolation layer portion over the side wall of the hole. In addition, in order to prevent the accumulation of an excessive amount of the polymer, which may cause the etching process to stop in an undesirable way, the etching removal of the isolation layer portion over the bottom of the hole is accomplished in a number of repeated cycles each including forming a new polymer layer and then removing it. In this way, it can be ensured that the metal layer is exposed without loss of the solation layer portion over the side wall of the hole and a top surface of the front-end component. As a result, undesirable exposure of the substrate or the front-end component's top surface is prevented, resulting in enhanced performance and yield of the semiconductor devices being fabricated.

In embodiments of the present invention, there is provided a method of fabricating a semiconductor device, which will be described in greater detail below with reference to the accompanying drawings and a few specific embodiments. From the detailed description, advantages and features of the invention will become more apparent. Note that the drawings are provided in a very simplified form not necessarily drawn to scale, and their only intention is to facilitate convenience and clarity in explaining the embodiments.

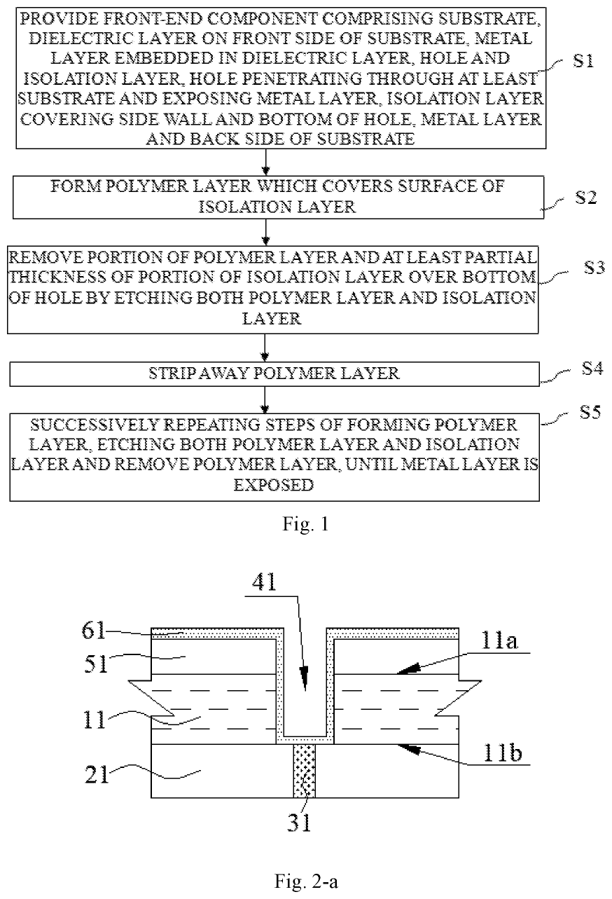

FIG. 1 schematically shows a flowchart of a method of fabricating a semiconductor device in accordance with an embodiment of the present invention. As shown in FIG. 1, the method includes the steps of:

S1) providing a front-end component including a substrate, a dielectric layer on a front side of the substrate, a metal layer embedded in the dielectric layer, a hole and an isolation layer, the hole penetrating through at least the substrate and exposing the metal layer, the isolation layer covering the hole's side wall and bottom and a back side of the substrate;

S2) forming a polymer layer which covers a surface of the isolation layer;

S3) removing a portion of the polymer layer and at least a partial thickness of a portion of the isolation layer over the bottom of the hole by etching both the polymer layer and the isolation layer;

S4) removing the polymer layer;

S5) successively repeating the steps of forming a polymer layer, etching both the polymer layer and the isolation layer and removing the polymer layer, until the metal layer is exposed.

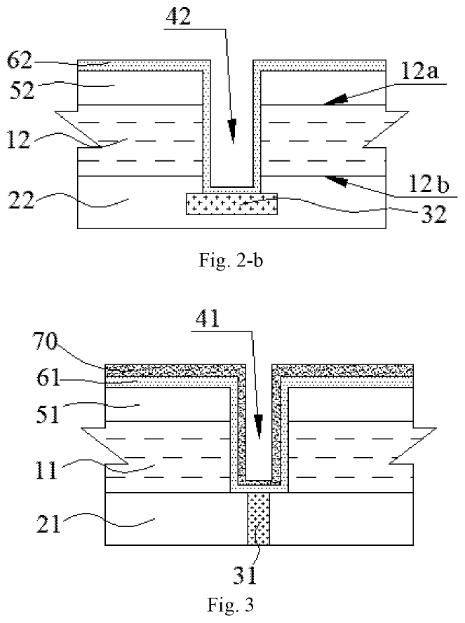

FIG. 2-a is a structural schematic of a front-end component according to an embodiment of the present invention. As shown in FIG. 2-a, the provided front-end component includes a substrate 11 having a front side 11b and a back side 11a opposing the front side 11b. The substrate 11 may be made of monocrystalline silicon, polycrystalline silicon, amorphous silicon or another semiconductor material based on Group III, IV and/or V element(s), such as gallium arsenide, silicon carbide, gallium nitride, etc. In this present embodiment, the material of the substrate 11 may be, for example, monocrystalline silicon. The front-end component further includes a dielectric layer 21 on the front side 11b of the substrate 11, a metal layer 31 embedded in the dielectric layer 21, a hole 41 and an isolation layer 61. The hole 41 penetrates through the substrate 11 so that the metal layer 31 is exposed in the hole 41, and the isolation layer 61 covers side walls and a bottom of the hole 41 and the back side 11a of the substrate 11. The isolation layer 61 may be formed of a material with a low dielectric constant, which contains an oxide or nitride, such as silicon dioxide or silicon nitride, as its main ingredient. The isolation layer 61 is formed to isolate a metal interconnection layer subsequently deposited within the hole 41 from the substrate 11 so as to prevent the material of the metal interconnection layer in the hole 41 from diffusing into the substrate 11 and thus degrading the performance of the semiconductor device being fabricated. Further, a passivation layer 51 may be formed on the back side 11a of the substrate 11 to provide the substrate 11 with protection, isolation and insulation. The passivation layer 51 may be formed of silicon dioxide or silicon nitride. In a specific embodiment with such a passivation layer 51 being provided, the isolation layer 61 may cover the side walls and the bottom of the hole 41 and a surface of the passivation layer 51. In this embodiment, the hole 41 may extend through both the passivation layer 51 and the substrate 11 but not into the dielectric layer 21. The metal layer 31 may constitute, for example, a through silicon via (TSV) penetrating through the dielectric layer 21.

FIG. 2-b is a structural schematic of a front-end component according to another embodiment of the present invention. As shown in FIG. 2-b, the hole 42 may further penetrate through a partial thickness of the dielectric layer 22. In this case, the provided front-end component includes a substrate 12 having a front side 12b and a back side 12a opposing the front side 12b. The front-end component further includes a dielectric layer 22 on the front side 12b of the substrate 12, a metal layer 32 embedded in the dielectric layer 22, a hole 42 and an isolation layer 62, the hole 42 penetrating through both the substrate 12 and a partial thickness of the dielectric layer 22 and exposing the metal layer 32, the isolation layer 62 covering the side walls and a bottom of the hole 42 and the back side 12a of the substrate 12. Additionally, a passivation layer 52 may be formed on the back side 12a of the substrate 12 to provide the substrate 12 with protection, isolation and insulation. The passivation layer 52 may be implemented as, for example, a silica layer. In a specific embodiment with such a passivation layer 52 being provided, the isolation layer 62 may cover the side walls and the bottom of the hole 42 and a surface of the passivation layer 52. In this embodiment, the hole 42 may extend through the passivation layer 52, the substrate 12 and a partial thickness of the dielectric layer 22, with the metal layer 32 being exposed therein. The metal layer 32 in the dielectric layer 22 may serve to, for example, extract a signal from the semiconductor device being fabricated.

A method of fabricating a semiconductor device according to an embodiment of the present invention will be described in detail below with reference to FIGS. 3 to 5. The method is applicable to both the cases shown in FIGS. 2-a and 2-b and will be explained with the case shown in FIG. 2-a as an example.

FIG. 3 schematically shows the formation of a polymer layer according to an embodiment of the present invention. As shown in FIG. 3, the polymer layer 70 may be formed by a plasma deposition process performed at a chamber pressure of from 25 mTorr to 35 mTorr, an RF power level of 2000-3000 W and a bias voltage of 45-55 V and using reaction gases including CH₂F₂, CH₃F and an oxygen-containing gas. For example, CH₂F₂, CH₃F and O₂ may be provided as the reaction gases at the flow rates of 140-160, 190-210 and 15-25 sccm, respectively, for a period of time of 6-8 s. Since the material of the polymer layer 70 has a relatively large molecular weight, the molecules will barely reach the bottom of the hole 41. For this reason, the resulting layer will be thicker over the substrate's back side (i.e., the top most surface when the shown structure is inverted) than over the side walls and the bottom of the hole 41. In other words, compared to the side walls and the bottom of the hole 41, the back side of the substrate (i.e., the top most surface when the shown structure is inverted) will be protected by a greater thickness of the polymer layer.

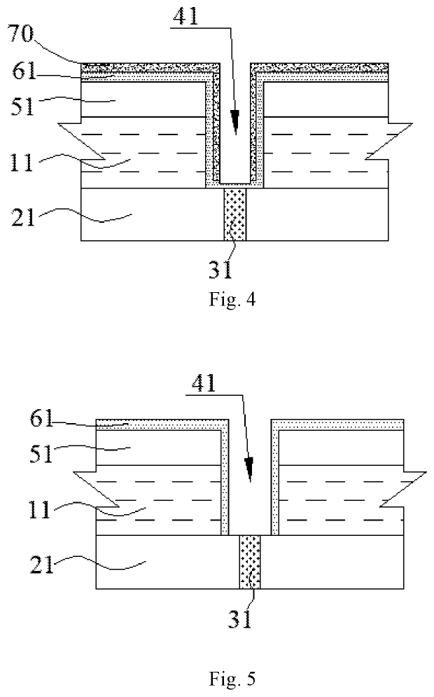

FIG. 4 schematically shows how the polymer layer and isolation layer are etched in accordance with an embodiment of the present invention. As shown in FIG. 4, the layer may be etched by a dry etching process, preferably a plasma etching process performed at a chamber pressure of from 10 mTorr to 20 mTorr, an RF power level of 1000-2500 W and a bias voltage of 1400-1600 V and using an gaseous etchant including NF₃, CH₃F, CHF₃ and an oxygen-containing gas. In the gaseous etchant, fluorine (F) is provided to react with silicon dioxide or silicon nitride in the isolation layer to produce volatile products, while carbon (C) serves as a source for the polymer which retards the progress of the etching process. The polymer deposited over the side wall of the hole 41 acts as a protective layer to make the etching process less isotropic, so that the etching occurs mainly at the bottom of the hole 41 to remove the polymer layer as well as at least a partial thickness of the isolation layer over the bottom of the hole 41. Since the etching rate increases with the fluorine content and decreases with the carbon content, a suitable etching rate can be obtained by properly adjusting the contents of the two elements in the gaseous etchant For example, NF₃, CH₃F, CHF₃ and O₂ may be provided as the gaseous etchant at the flow rates of 70-90, 50-70, 40-60and 8-12 sccm, respectively, for a period of time of 13-17 s. The use of a high bias voltage, e.g., 1400-1600 V enable the low molecular weight NF₃ and CHF₃ to reach the bottom of the hole 41, thereby ensuring their full reaction with the material of the isolation layer.

FIG. 5 shows a structure with the metal layer being exposed according to an embodiment of the present invention. As shown in FIG. 5, the polymer layer may be removed by an ashing process. Specifically, the ashing process may be performed at a chamber pressure of from 15 mTorr to 25 mTorr, an RF power level of 2500-2700 W and a bias voltage of 0 V and using an ashing gas containing oxygen. In this process, the front-end component is heated and exposed to an oxygen plasma or ozone so that the polymer layer 70 is removed by a chemical reaction. The ashing temperature may range from 250° C. to 300° C. For example, O₂ may be provided as the ashing gas for a period of time of 23-27 s. By removing the formed polymer layer, the etching process can be prevented from stopping in an undesirable way due to the accumulation an excessive amount of the polymer. The polymer layer is a product of certain reactions between the plasma of the reaction gases containing fluorine and carbon and etching products, which can protect the side wall from being etched and enhance the directionality of the etching process. Oxygen (O₂) can reactively consume carbon in the polymer layer, leading to an increased F/C ratio and a consumption of the polymer layer. The removal of the polymer layer following the etching process is necessary because it may become a source of particles and other contaminants that might increase the surface defect density of the devices being fabricated and thus harm that performance, yield and reliability. With the above-discussed method, the polymer layer can be effectively removed.

Next, with combined reference to FIGS. 3 to 5, the steps of forming a polymer layer, etching both the polymer layer and the isolation layer and removing the polymer layer are successively repeated until the isolation layer portion covering the bottom of the hole is completed removed to expose the metal layer 31. The number of repetitions may depend on the thickness of the isolation layer portion covering the bottom of the hole, as long as the other isolation layer portion that covers both the side wall of the hole 41 and the top surface of the front-end component is not partially lost when the metal layer 31 is exposed. As a result, when another metal is subsequently filled in the hole 41 to interconnect with the metal layer 31, it will not diffuse into the substrate 11 because of the presence of the isolation layer 61. In addition, the isolation layer portion covering the back side of the substrate (the top most surface when the shown structure is inverted) is also not lost at all, providing protection to the front-end component. According to this embodiment, since the etching process stops at the metal layer 31, the latter is washed without being protected by an insulating layer. Therefore, in order to avoid damage to the metal layer 31, the washing may be accomplished in a physical manner using a weak cleaning solvent rather than using a strong cleaning solvent that may damage the metal layer 31.

In summary, by successively repeating the steps of forming a polymer layer, etching both the polymer layer and the isolation layer and removing the polymer layer, the isolation layer portion covering the bottom of the hole is completed removed to expose the metal layer. During the etching removal of the isolation layer portion over the bottom of the hole, a polymer is deposited to protect the isolation layer portion over the side wall of the hole. In addition, in order to prevent the accumulation of an excessive amount of the polymer, which may cause the etching process to stop in an undesirable way, the etching removal of the isolation layer portion over the bottom of the hole is accomplished in a number of repeated cycles each including forming a new polymer layer and then removing it. In this way, it can be ensured that the metal layer is exposed without loss of the solation layer portion over the side wall of the hole and a top surface of the front-end component. As a result, undesirable exposure of the substrate or the front-end component's top surface is prevented, resulting in enhanced performance and yield of the semiconductor devices being fabricated.

It is noted that the embodiments disclosed herein are described in a progressive manner, with the description of each embodiment focusing on its differences from others. Reference can be made between the embodiments for their identical or similar parts. Since the method embodiments correspond to the apparatus embodiments, they are described relatively briefly, and reference can be made to the apparatus embodiments for details in the method embodiments.

The description presented above is merely that of a few preferred embodiments of the present invention and does not limit the scope thereof in any sense. Any and all changes and modifications made by those of ordinary skill in the art based on the above teachings fall within the scope as defined in the appended claims.

What is claimed is:

1. A method of fabricating a semiconductor device, comprising:
providing a front-end component comprising a substrate, a dielectric layer on a front side of the substrate, a metal layer embedded in the dielectric layer, a hole and an isolation layer, the hole penetrating through at least the substrate and exposing the metal layer, the isolation layer covering side walls and a bottom of the hole, the metal layer and a back side of the substrate;
forming a polymer layer which covers a surface of the isolation layer;
removing a portion of the polymer layer and at least a partial thickness of a portion of the isolation layer over the bottom of the hole by etching both the polymer layer and the isolation layer;
removing the polymer layer; and
successively repeating the steps of forming a polymer layer, etching both the polymer layer and the isolation layer and removing the polymer layer, until the metal layer is exposed.

2. The method of claim 1, wherein the polymer layer is formed by a plasma deposition process performed at a plasma chamber pressure of from 25 mTorr to 35 mTorr, an RF power level of 2000-3000 W and a bias voltage of 45-55 V using mixed reaction gases including CH₂F₂, CH₃F and O₂.

3. The method of claim 2, wherein CH₂F₂ is provided at a flow rate of 140-160 sccm, CH₃F is provided at a flow rate of 190-210 sccm and O₂ is provided at a flow rate of 15-25 sccm, for a period of time of 6-8 s.

4. The method of claim 1, wherein the polymer layer and the isolation layer are etched by a plasma etching process performed at a plasma chamber pressure of from 10 mTorr to 20 mTorr, an RF power level of 1000-2500 W and a bias voltage of 1400-1600 V using mixed reaction gases including NF₃, CH₃F, CHF₃ and O₂.

5. The method of claim 4, wherein NF₃ is provided at a flow rate of 70-90 sccm, CH₃F is provided at a flow rate of 50-70 sccm, CHF₃ is provided at a flow rate of 40-60 sccm and O₂ is provided at a flow rate of 8-12 sccm, for a period of time of 13-17 s.

6. The method of claim 1, wherein the polymer layer is removed by an ashing process performed for a period of time of 23-27 s at a plasma chamber pressure of from 15 mTorr to 25 mTorr, an RF power level of 2500-2700 W and a bias voltage of 0 V using a reaction gas containing O₂ introduced at a flow rate of 800-1200 sccm.

7. The method of claim 1, wherein the steps of forming a polymer layer, etching both the polymer layer and the isolation layer and removing the polymer layer are successively repeated for 8 to 10 times.

8. The method of claim 1, wherein the hole extends through the substrate so that the metal layer is exposed therein.

9. The method of claim 1, wherein the hole extends through both the substrate and a partial thickness of the dielectric layer so that the metal layer is exposed therein.

10. The method of claim 1, wherein the polymer layer has a thickness of from 5 nm to 20 nm.
